(19) United States
(12) Patent Application Publication
(10) Pub. No.: US 2008/0223522 A1
(43) Pub. Date: Sep. 18, 2008

(54) PLASMA PROCESSING APPARATUS

(76) Inventors: Hiroyuki Kobayashi, Kodaira (JP); Kenetsu Yokogawa, Tsurugashima (JP); Masaru Izawa, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/835,455

(22) Filed: Aug. 8, 2007

(30) Foreign Application Priority Data
Mar. 16, 2007 (JP) 2007-068671

(51) Int. Cl. H01L 21/306

(52) U.S. Cl. 156/345.25

(57) ABSTRACT

The present invention provides a plasma processing chamber mounted with a function capable of determining the state of a temperature rise in a processing chamber even if a thermometer is not mounted in the processing chamber. In a plasma processing apparatus including: a processing chamber for subjecting a sample to be processed to plasma processing; means for supplying the processing chamber with gas; exhaust means for reducing pressure in the processing chamber; a high-frequency power source for generating plasma; and an electrode on which the sample to be processed is placed, there is provided a plasma emission monitor for determining an end point of temperature raise discharge and means for determining an end point of temperature raise discharge, both of which are used for determining an end point of temperature raise discharge performed before the plasma processing.

### CLAIM OF PRIORITY

The present invention application claims priority from Japanese application JP2007-068671 filed on Mar. 16, 2007, the content of which is hereby incorporated by reference into this application

### BACKGROUND OF THE INVENTION

(1) Field of the Invention

The present invention relates to a semiconductor manufacturing apparatus, and in particular to a plasma processing apparatus.

(2) Description of the Related Art

A plasma etching apparatus and a plasma CVD apparatus have been widely used in the manufacturing process of a semiconductor device such as a DRAM and a microprocessor.

The etching apparatus is provided with means for measuring the emission spectrum of plasma so as to determine the end point of etching or cleaning or so as to determine the uniformity of a plasma distribution. The wavelength profile of the emission spectrum reflects the density of molecules and radicals in the plasma, so the end point of etching or cleaning can be found by investigating, for example, a temporal change in the intensity of a specified wavelength.

The wavelength profile of the emission spectrum includes not only the information of the density of molecules and radicals but also the information of the vibration and rotational excitation distribution (or the vibrational and rotational population) of the molecules and the radicals. The rotational excitation distribution of the molecules and the radicals can be evaluated as a rotational temperature in the state of thermal equilibrium. As a method for measuring a rotational temperature have been known methods disclosed in Japanese Patent Application Laid-Open Publication No. H01-212776, WIPO Patent Publication No. WO2004-085704, and Japanese Patent Application Laid-Open Publication Nos. 2005-72347 and 2005-235464, for example.

In Japanese Patent Application Laid-Open Publication No. H01-212776 is described a method for finding the temperature of gas from an emission spectrum in a plasma processing apparatus and is described the capability of measuring the temperature of a substrate from the temperature of gas. In WIPO Patent Application No. WO2004-085704 and Japanese Patent Application Laid-Open Publication No. 2005-72347 are disclosed measuring a gas temperature by measuring a rotational temperature in a processing apparatus and correcting the measured value of the density of radicals on the basis of the measured gas temperature. In Japanese Patent Application Laid-Open Publication No. 2005-235464, measuring the rotational temperature of a molecule from an emission spectrum is disclosed as means for investigating a gas temperature in a plasma generating apparatus.

One of problems in the processing of a semiconductor device using plasma is stability in mass production. This stability in mass production means that, for example, when an etching apparatus is restarted from a non-operating state, a processed shape in the surface of a sample to be processed, which is processed for the first time, is equal to a processed shape in the surface of a sample to be processed, which is processed for several tenth time, that is, there is no variations in the processed shape between the samples to be processed. One factor of instability in mass production, which causes a difference in the processed shape between the samples to be processed, is a change in the temperatures of the inside wall of a processing chamber and of a structure in the processing chamber. When these temperatures are changed, the probabilities of absorption and reflection of a reactive gas on the surfaces of the materials of the inside wall and the structure are changed and hence the distribution in the surface of the sample to be processed of the flux of the reactive gas entering the sample to be processed is changed. Further, a change in the temperature of the structure in the processing chamber causes a change in the temperature of a processing gas. When the temperature of the processing gas is changed, the density of the processing gas is changed. As a result, this causes a change in the processed shape between the samples to be processed.

To reduce variations in the processed shape between the samples to be processed, generally, when the etching apparatus is restarted from a non-operating state, temperature raise discharge for heating (conditioning) the interior of the processing chamber to a desired temperature is performed and after the temperature in the processing chamber is sufficiently raised, the processing of the sample to be processed is started. A discharge time required to raise the temperature is determined, for example, on the basis of measurement by a thermometer mounted in the processing chamber. This temperature measurement is generally performed by the use of a thermocouple thermometer, a fluorescence thermometer, a radiation thermometer, or the like.

However, when the fluorescence thermometer or the thermocouple thermometer is used, the thermometer is embedded in the inside wall or the like, so the thermometer does not always measure the temperature of the surface of the inside wall of the processing chamber which the processing gas is in contact with. Further, to mount temperature measuring means, a part of the processing apparatus needs to be worked, for example, to make a space to set a temperature measuring means. Still further, the radiation thermometer can measure the temperature of the surface of a part but requires an observation window to be formed. Still further, it is difficult for the radiation thermometer to measure low temperature close to the room temperature with high accuracy.

In addition, the temperature of gas having a direct effect on the process cannot be directly measured by these methods. Moreover, a mass production apparatus is not always mounted with temperature measurement means for measuring temperature in the processing chamber. In this case, a time required to perform temperature raise discharge for heating the interior of the processing chamber needs to be previously determined, for example, in the following manner: a thermometer is temporarily mounted in the processing chamber; a correlation between a discharge time and the temperature of the inside wall of the processing chamber is measured by the use of the thermometer; and then the time required to perform the temperature raise discharge is determined on the basis of the measured correlation.

On the other hand, in Japanese Patent Application Laid-Open Publication No. H01-212776, WIPO Patent Publication No. WO2004-085704, and Japanese Patent Application Laid-Open Publication Nos. 2005-72347 and 2005-235464 is disclosed measuring the rotational temperature of gas in the plasma processing apparatus, but giving consideration to the control of the temperature raise discharge is not disclosed.

### SUMAMRY OF THE INVENTION

An object of the present invention is to provide a plasma processing apparatus having the function of grasping the state of temperature in a processing chamber with ease and precision and of controlling suitable temperature raise discharge.

Another object of the present invention is to provide a plasma processing apparatus having the function of measuring the temperature of gas in a processing chamber with accuracy and of determining an end point of temperature raise discharge and having an excellent stability in mass production.

According to an embodiment having a typical configuration of the present invention, in a plasma processing apparatus comprising: a processing chamber for processing a sample to be processed by using a plasma; means for supplying a processing gas to the processing chamber; exhaust means for reducing pressure in the processing chamber; a high-frequency power source for generating the plasma; and a sample holding electrode on which the sample to be processed is placed, the plasma processing apparatus further comprising: a plasma emission monitor for determining an end point of temperature raise discharge; and a unit for determining an end point of temperature raise discharge, both of which are used for determining an end point of temperature raise discharge performed before the plasma processing.

According to the present invention, it is possible to provide plasma processing chamber that can determine the state of temperature in the processing chamber on the basis of the measurement of a gas temperature and hence can find the condition of the temperature in the processing chamber and can control suitable temperature raise discharge even if a thermometer is not mounted.

### BRIEF DESCRIPTION OF THE DRAWINGS

These and other features, objects and advantages of the present invention will become more apparent from the following description when taken in conjunction with the accompanying drawings wherein:

FIG. 1 is a schematic diagram of a first embodiment to which the present invention is applied to a parallel flat plate type ECR plasma processing apparatus;

FIG. 2A is a diagram illustrating, on an enlarged scale, a main portion of the first embodiment;

FIG. 2B is a diagram illustrating a position where a light collection head is mounted in the first embodiment;

FIG. 3 is a block diagram showing the configuration of a controller in the first embodiment;

FIGS. 4A and 4B are graphs illustrating a method for operating the plasma processing apparatus according to the first embodiment;

FIG. 5 is a diagram describing a method for evaluating a rotational temperature according to the first embodiment;

FIG. 6 is a graph of experiment data for illustrating the dependence of gas temperature on a discharge time according to the first embodiment;

FIG. 7 is a graph illustrating the difference in a change in gas temperature between measurement positions according to the first embodiment;

FIG. 8A is a graph illustrating a change in temperature in a processing chamber caused by a heat cycle according to the first embodiment;

FIG. 8B is a graph illustrating a change in temperature in a processing chamber caused by another heat cycle according to the first embodiment;

FIG. 8C is a graph illustrating a change in temperature in a processing chamber caused by still another heat cycle according to the first embodiment;

FIG. 9A is a graph illustrating a discharge time for raising temperature according to the first embodiment;

FIG. 9B is a graph illustrating another discharge time for raising temperature according to the first embodiment;

FIG. 10 is a diagram illustrating a second embodiment to which the present invention is applied to a plasma processing apparatus; and

FIG. 11 is a diagram illustrating a third embodiment to which the present invention is applied to a plasma processing apparatus.

### DETAILED DESCRIPTION OF THE PREFERRED EMBODIMENTS

According to a typical embodiment of the present invention, in a plasma processing apparatus having a spectroscopic measurement system for measuring the emission of plasma, the rotational temperature of a molecule and a radical of gas is calculated from measured plasma emission and the state of a temperature raise in a chamber is determined from the rotational temperature. In a process in which molecules or radicals of gas whose electronic excited state is in a ground state are excited to an electronic higher level by electron impact and soon spontaneously emit light to relax to an electronic lower level, in many cases, the rotational temperature found from an emission spectrum is generally considered to be equal to the temperature of gas of a background. The temperature of gas reflects two of direct heating by plasma and the surface temperature of a part in contact with the gas, so if the temperature of the part changes, the temperature of gas will change. Further, the rotational temperatures of the molecule and the radical also change similarly in accordance with a change in the temperature of gas. For this reason, the measurement of the rotational excited states of molecules and radicals of the gas in a processing chamber can provide the information of the temperatures of the part and the gas in the processing chamber.

### Embodiment 1

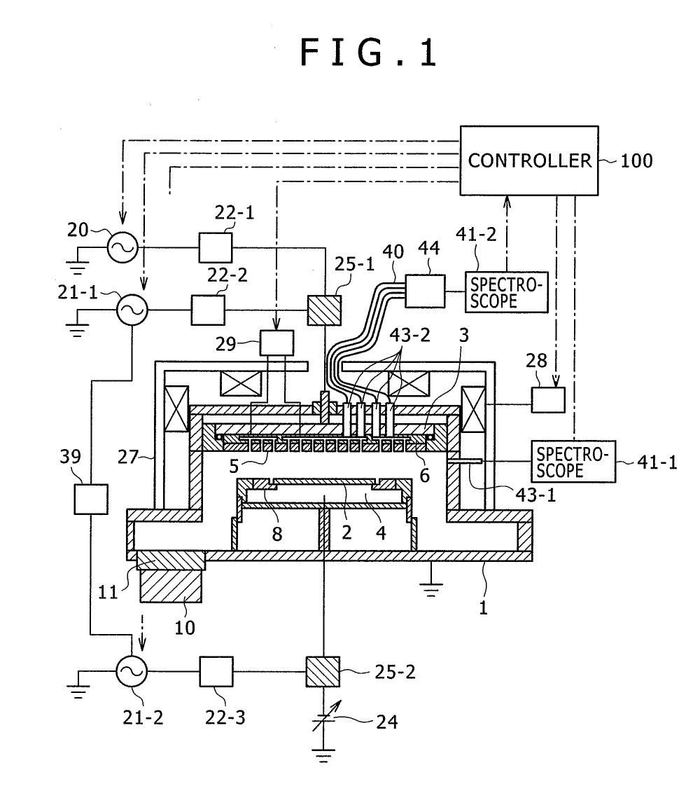

Hereinafter, a first embodiment of the present invention will be described with reference to FIG. 1 to FIG. 9.

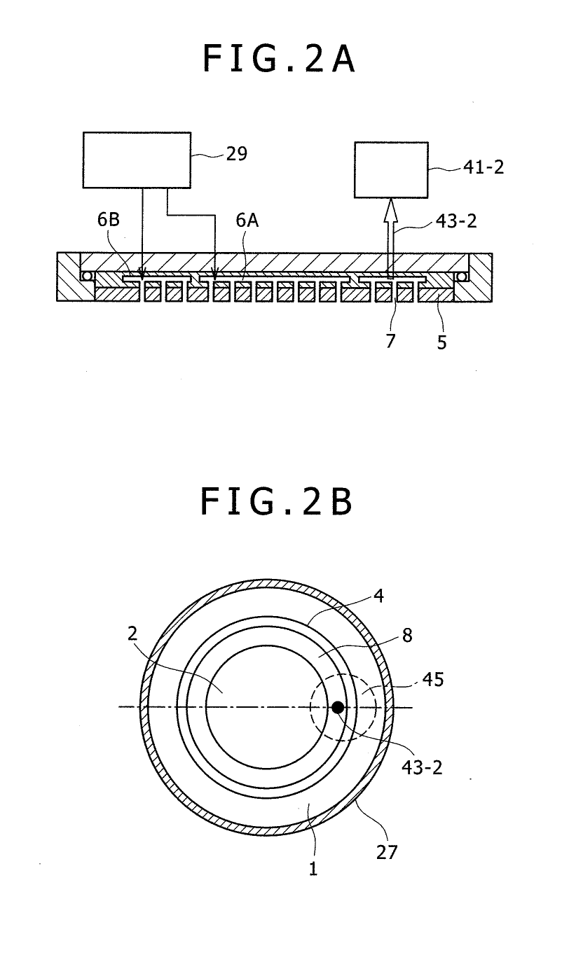

FIG. 1 shows a schematic diagram of a first embodiment to which the present invention is applied to a parallel flat plate type ECR plasma processing apparatus. FIG. 2A and FIG. 2B are diagrams illustrating, on an enlarged scale, a main portion in FIG. 1.

An antenna 3 for radiating an electromagnetic wave is mounted in parallel to a stage 4 on which a sample 2 to be processed is placed in the upper portion of a processing chamber 1. The processing chamber 1 is grounded. A shower plate 5 is mounted below the antenna 3 via a gas dispersion plate 6. Processing gas supplied from a processing gas source 29 is dispersed in the gas dispersion plate 6 and is supplied into the processing chamber 1 through gas holes 7 formed in the shower plate 5.

Further, the gas dispersion plate 6, as shown as one example in FIG. 2A, may be divided into two areas of an inside area 6A and an outside area 6B. With this, the flow rate and composition of gas supplied from the processing gas source 29 can be controlled independently in the inside area 6A and in the outside area 6B of the gas dispersion plate 6, in other words, in the vicinity of the center and in the vicinity of the outer periphery of the sample to be processed, whereby a processed size can be made uniform in the surface of the sample to be processed.

Returning to FIG. 1, the processing chamber 1 is mounted with exhaust means 10 such as a turbo molecular pump via a butterfly valve 11, the exhaust means 10 reducing pressure in the processing chamber 1. The antenna 3 has a high-frequency power source 20 connected thereto via a matching device 22-1 and a filter 25-1 so as to generate plasma. A plurality of solenoid coils 26 and a yoke 27 are mounted outside the processing chamber 1 so as to produce a magnetic field. Each of the solenoid coils 26 is constructed so as to be able to control the intensity of the magnetic field by a magnetic field control unit 28.

In the processing chamber 1, plasma is effectively generated by electronic cyclotron resonance produced by the interaction between high-frequency power and the magnetic field, the high-frequency power being radiated from the antenna 3 for generating plasma. Further, the production distribution of the plasma and the transportation of the plasma in the processing chamber 1 can be controlled by controlling a magnetic field distribution by the magnetic field control unit 28.

The antenna 3 has a bias power source 21-1 connected thereto via a matching device 22-2 and the filter 25-1, the bias power source 21-1 applying high-frequency bias power to the antenna 3. The filter 25-1 is provided so as to prevent the high-frequency power for generating plasma from flowing into the high-frequency bias power source 21-1 for the antenna 3 and so as to prevent the high-frequency bias power to be applied to the antenna 3 from flowing into the high-frequency source power 20 for generating plasma. The stage 4 has a bias power source 21-2 connected thereto via a matching device 22-3 and a filter 25-2 so as to accelerate ions injected into the sample 2 to be processed.

High-frequency bias power to be applied to the stage 4 has the same frequency as the high-frequency bias power to be applied to the antenna 3. The phase difference between the high-frequency bias power to be applied to the antenna 3 and the high-frequency bias power to be applied to the stage 4 is controlled by a phase control device 39. When this phase difference is brought to 180°, the confinement of plasma is enhanced and the flux and energy of ions injected into the side walls of the processing chamber 1 are decreased. With this, the quantity of foreign substances produced by the consumption of the wall and the like can be decreased and the lives of the coatings of a wall material and the like can be elongated.

Further, the stage 4 has a DC power source 24 connected thereto via the filter 25-2 so as to secure the sample 2 to be processed by means of electrostatic chuck. The stage 4 has a passage (not shown) formed therein so as to control (cool) temperature, the passage having an insulating refrigerant such as Fluorinert (registered Trademark) passed therethrough. The temperature of the refrigerant is controlled so as to be lower than the control target temperature of the sample 2. Further, in the stage 4, helium gas can be supplied to the bottom surface of the sample 2 so as to transmit the heat of the sample 2 to the stage 4 to cool the sample 2. Still further, to control temperature independently in the inside portion of the sample 2 and in the outer peripheral portion of the sample 2, although not shown in the drawing, the stage 4 is provided with a gas line for supplying the helium gas to the inside portion of the bottom surface of the sample 2 and a gas line for supplying the helium gas to the outer peripheral portion of the bottom surface of the sample 2. The shower plate 5 is also provided with cooling means for preventing a temperature raise.

To determine the end points of etching and cleaning, the emission from plasma is collected by a light collection head 43-1 and is spectroscopically measured by a spectroscope 41-1.

Further, to measure a plasma emission distribution in the radial direction of the sample 2, the emission from plasma can be collected by a plurality of light collection heads 43-2 disposed at a plurality of positions corresponding to from the center to the outer periphery of the stage 4. Each of the light collection heads 43-2 is constructed so as to measure the interior of a plasma generating space in the processing chamber 1 via the hole 7 formed in the shower plate 5. That is, in place of setting a thermometer in the processing chamber 1, the rotational temperature of gas in the processing chamber 1 is founded on the basis of the measured temperature of the gas and the state of temperature in the processing chamber 1 can be determined on the basis of the found rotational temperature of the gas. Here, information obtained by the light collection heads 43-2 can be used also for the measurement of a temperature distribution or the like in the surface of the sample 2 to be processed.

If to find the rotational temperature of the gas is only one object, the number of the light collection heads 43-2 may be one. Further, to measure the rotational temperature of the gas, it is preferable that the light collection heads 43-2 are disposed at positions corresponding to the interior of an area shown by a circle of a broken line in FIG. 2B (an area near the outer periphery of the stage 4 and the outer periphery of the shower plate 5). As for holes for collecting light of the respective light collection plates 43-2, it suffices to form the holes exclusive for collecting light in positions corresponding to parts of many gas holes 7 formed in the shower plate 5.

Plasma light collected by the light collection heads 43-2 is transmitted by a plurality of optical fibers 40 and is spectroscopically measured by a spectroscope 41-2. Since the light collected by the light collection heads 43-2 is divided by the plurality of optical fibers 40, the light can be transmitted to the spectroscope 41-2 by switching a measuring channel by means of, for example, a multiplexer 44. Of course, it is also possible to use a method in which optical fibers are arranged without using a multiplexer and in which the plasma light is measured as a two-dimensional image formed on a CCD placed in a spectroscope, the two-dimensional image being composed of one dimension of channel and another dimension of a wavelength.

Further, it is desirable that the spectroscope 41-1 can measure a wide range of wavelength even if a wavelength resolution is slightly low, for example, as low as 1 nm or more. However, it is desirable that the spectroscope 41-2 used for measuring the gas temperature has as high a wavelength resolution as 1 nm or less (for example, 0.1 nm).

Data measured by the spectroscopes 41-1 and 41-2 is sent to and processed by a controller 100, and the power source 20, the bias power source 21, the magnetic field control device 28, the processing gas source 29, and the phase control device 39 are controlled on the basis of the obtained data.

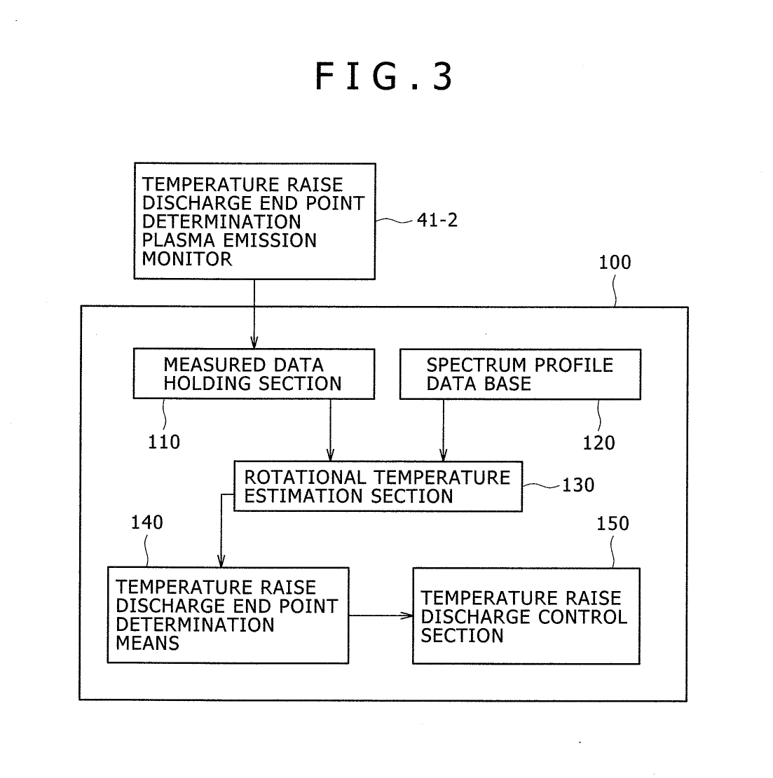

In FIG. 3 is shown a block diagram of the controller 100 of the plasma processing apparatus. The controller 100 is constructed of: a measured data holding section 110 for holding measured data of a spectrum profile in the processing chamber 1, the measured data being measured by the spectroscope 41-2; a spectrum profile data base 120 for holding data of spectrum profiles corresponding to a plurality of rotational temperatures of a molecule of each gas so as to measure a rotational temperature, the data being previously found by calculation and being held for the gas; a rotational temperature estimation section 130 for estimating the rotational temperature of the molecule of the gas from the comparison between the measured data of the spectrum profile and the data of the spectrum profile; end point determination means 140 for determining an end point of temperature raise discharge on the basis of the estimated rotational temperature of the molecule of the gas; and temperature raise discharge control section 150 for performing an overall control of the temperature raise discharge in the processing chamber 1.

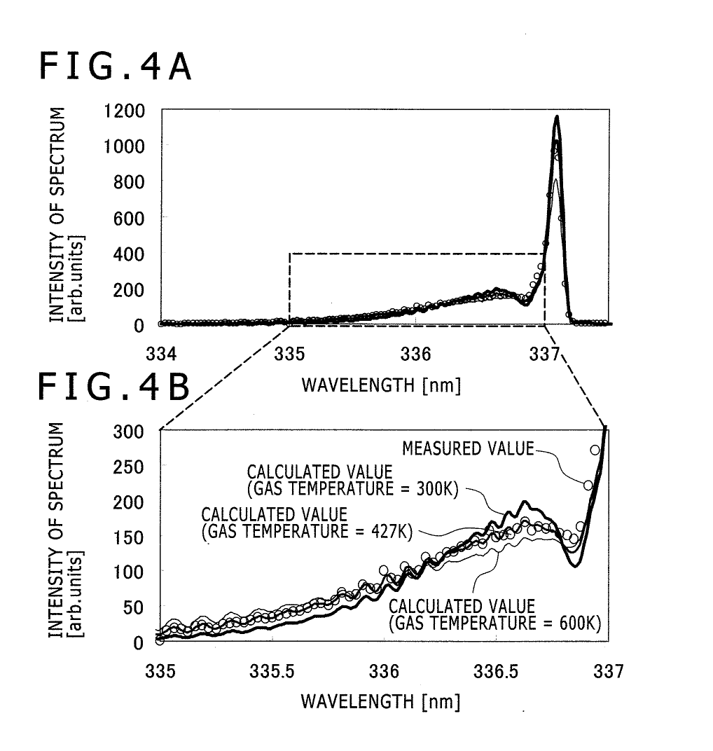

Next, a method for measuring a rotational temperature will be described, the method being used for estimating the gas temperature at the time of temperature raise discharge in the rotational temperature estimation section 130. FIGS. 4A and 4B show the comparison between the calculated value of a spectrum profile of a nitrogen molecule (value held in the spectrum profile data base 120) and the measured value thereof (value in the measured data holding section 110) as an example. A mixed gas of nitrogen and CF₄ is used as discharge gas. FIG. 4A shows a range of wavelength from 334 nm to 338 nm and FIG. 4B shows, in enlargement, a range of wavelength from 335 nm to 337 nm in FIG. 4A. Circles show measured values. Calculated values are found by assuming the rotational temperature of a nitrogen molecule to be three values of 300 K (bold line), 427 K (middle line), and 600 K (slender line).

As can be seen from FIGS. 4A and 4B, the profile of a spectrum changes according to the rotational temperature of the nitrogen molecule. In the example shown in FIGS. 4A and 4B, the measured spectrum profile is in good agreement with the calculated values of a spectrum profile when the rotational temperature is assumed to be 427 K. The rotational temperature estimation section 130 of the controller 100 compares the measured spectrum profile with a spectrum profile found by calculation and searches a rotational temperature at which the measured spectrum profile is in best agreement (best fits in) with a spectrum profile found by calculation to find the rotational temperature of a molecule (here, 427 K). The rotational temperature of a molecule found in this manner can be considered to be the temperature of gas of the background as described above.

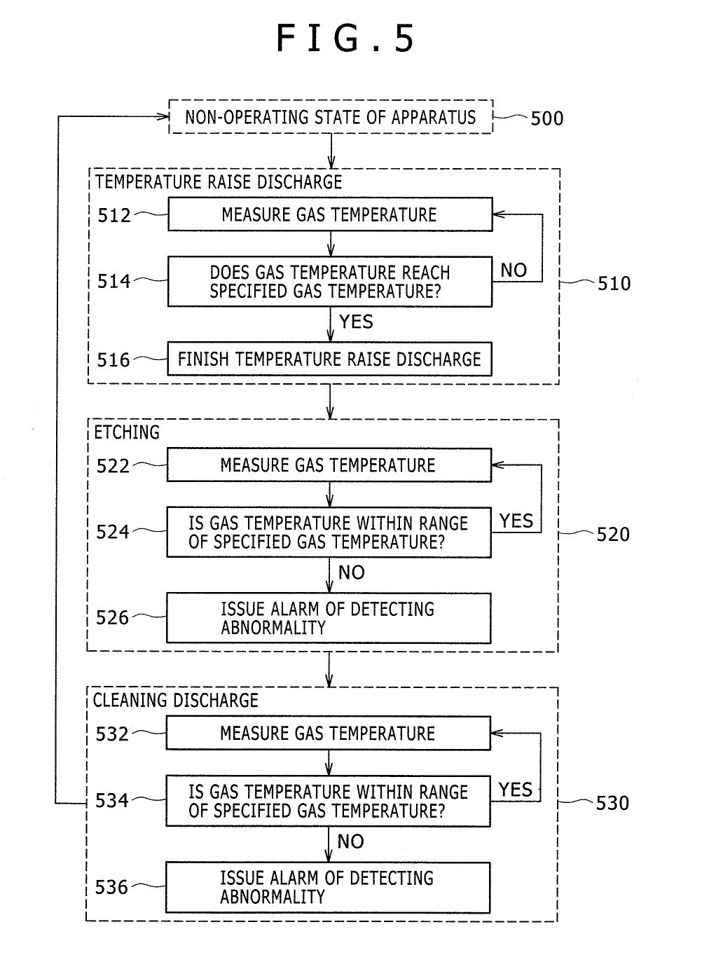

Next, a method for controlling the operations of the end point determination means 140 and the temperature raise discharge control section 150 of the controller 100, that is, temperature raise discharge based on gas temperature measurement will be described with reference to FIG. 5. In the example shown in FIG. 5, not only temperature raise discharge for heating the interior of the processing chamber 1 of the plasma processing apparatus but also etching and cleaning discharge are controlled. That is, an example of use of gas temperature measurement in an operation cycle of non-operating state 500 of the plasma processing apparatus→temperature raise discharge 510→etching 520→cleaning discharge 530→ . . . →etching 520→cleaning discharge 530→non-operating state 500 of the plasma processing apparatus. Here, at the time of temperature raise discharge 510, a dummy wafer is placed on the stage 4 and is subjected to plasma discharge (temperature raise discharge), whereby the interior of the processing chamber 1 is heated to a desired temperature. At the time of etching 520, a wafer of a sample to be processed is placed on the stage 4 and is subjected to etching processing by plasma. At the time of cleaning discharge 530, a wafer such as a dummy wafer is not placed on the stage 4 and plasma discharge (cleaning discharge) is performed to clean the interior of the processing chamber 1.

First, a gas temperature is measured (512) at the time of temperature raise discharge (510). Then, when it is detected that the gas temperature reaches a specified temperature (514) or that the quantity of temporal change in the gas temperature reaches a specified value, this is determined as an end point of temperature raise and the temperature raise discharge is finished (516).

In this regard, gas temperature measurement based on the rotational temperature can be used also for detecting an abnormality in the plasma processing apparatus and an abnormality in the etching process. For example, a gas temperature is measured (522, 532) during the etching processing (520) or the cleaning processing (530) on the basis of the rotational temperature. Then, when the measured gas temperature is within a specified range, the processing is continued just as it is (524, 534). When the measured gas temperature becomes larger or smaller than a specified value, or when the pattern of a change in the gas temperature shows a temporal change different from a normal pattern, an alarm is issued by displaying the detection of abnormality on a control panel (526, 536). Of course, discharge may be automatically stopped in the middle of the processing.

Not only the gas temperature measured near the outer periphery of the sample but also the gas temperature measured near the center of the sample may be used for the gas temperature used for detecting the abnormality. Further, it is desirable that the gas temperature or the progression of the gas temperature is displayed in real time on the display of an operating panel or the like.

Here, in this embodiment, the plasma light is collected via the holes of the shower plate, but in place of the holes a light collection head may be mounted in the portion of quartz or the like mounted outside the shower plate to measure the plasma light.

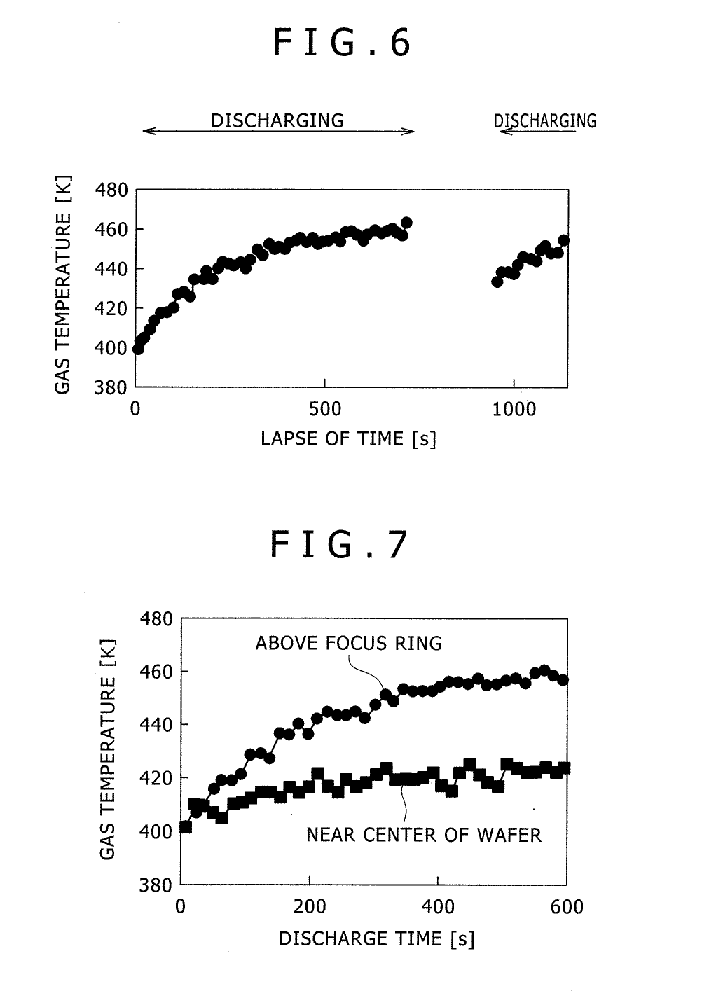

Next, a temporal change in a rotational temperature, that is, gas temperature will be described by taking FIG. 6 as an example. FIG. 6 shows a temporal change in a gas temperature, which is calculated by the analysis of a spectrum measured via the holes of the shower plate directly above a focus ring. This measurement is performed by starting discharge from a state where the plasma processing apparatus is left for several hours to once cool the wall and parts in the processing chamber to as low a level as the room temperature.

Immediately after the discharge is started, the gas temperature is 400 K and a rotational temperature rises with the duration of discharge. When one minute passes after the start of discharge, a rising speed is about 20 K/min, but when 600 seconds pass, a temperature rise becomes null and the rotational temperature becomes nearly constant at about 460 K. Stopping a rise in the gas temperature means that the temperatures of the inside wall and the stage of the processing chamber are sufficiently raised and brought to a stable state.

In this experiment, the discharge was performed for 720 seconds and then the plasma was once turned off and the discharge was again started after about 200 seconds passed. When the discharge was again started, the gas temperature at the beginning was 430 K, which was 30 K lower than the gas temperature of 460 K immediately before the end of the first discharge. This is because the temperature in the processing chamber was lowered. However, the gas temperature at the beginning was 30 K higher than the rotational temperature of 400 K immediately after the start of the first discharge, which means that the temperature in the processing chamber was not quite lowered to as low a level as the room temperature.

From the result shown in FIG. 6, by measuring the rotational temperature of a gas molecule, that is, the gas temperature, it is possible to recognize the state of temperature in the processing chamber, in other words, whether the temperature in the processing chamber is sufficiently raised or is lowered to as low a level as the room temperature or is not quite lowered.

In this regard, while an example for finding the rotational temperature from the emission spectrum of a nitrogen molecule is shown in FIG. 4A and 4B, the molecule whose rotational temperature is to be measured may be a molecule other than nitrogen, that is, the molecule of oxygen or chlorine, of course, does not need to be a diatomic molecule but may be a molecule composed of three or more atoms.

Further, it is also recommended to positively excite a molecule by laser and to measure an emitted spectrum. In this case, a device such as laser needs to be disposed in the processing chamber but the temperature of the gas can be measured with greater accuracy. Moreover, the temperature of the gas can be also measured by a method for measuring an absorption spectrum.

Still further, while the discharge gas of the mixture of nitrogen and CF₄ was used in the example shown in FIGS. 4A and 4B, if gas not containing gas suitable for the measurement of the rotational temperature, for example, nitrogen or oxygen is used in the temperature raise discharge or the etching discharge, it is recommended to add a small amount of nitrogen gas or the like as a tracer gas to a processing gas to be supplied into the processing chamber within a range in which the tracer gas does not have an effect on the process and the temperature raise as much as possible.

Further, when the discharge gas contained helium and argon, there are cases where the rotational excitation distribution of a molecule found from an emission spectrum is alienated from the temperature of the gas under the influence of these metastable excited atoms. For this reason, to measure the gas temperature, there may be employed the step of performing discharge in a gas system not containing these atoms.

Still further, there is also a method of evaluating a rotational excitation distribution as the rotational temperature of one temperature by fitting even when the rotational excitation distribution is alienated from the Boltzmann distribution. However, it is desirable to employ a method of finding a rotational excitation distribution as a plurality of (two or more) separate rotational temperatures and of removing the information of the rotational temperature not reflecting the gas temperature of the background.

Next, the importance of an observation position when the gas temperature is measured will be described. FIG. 7 shows the difference when the dependence of discharge time on the gas temperature was measured at different positions. One graph shows a gas temperature found from a spectrum measured via the holes of the shower plate disposed nearly above the center of the wafer, whereas another graph shows a gas temperature found from a spectrum measured via the holes of the shower plate disposed directly above the focus ring. The latter shows that gas temperature is raised 60 K with the discharge time, whereas the former shows that the gas temperature is raised as little as about 20 K with the discharge time. This is caused by the fact that since the sample and the shower plate are cooled and hence are not much raised in temperature even if the discharge is performed, the gas temperature near the center of the sample is not much raised.

Thus, to obtain the information of the temperature in the processing chamber from the measurement of the rotational temperature, it is desirable to measure the temperature of gas near a portion easily raised in temperature by the discharge, in this case, in the area 45 shown in FIG. 2B, that is, near the outer periphery of the stage 4 and the outer periphery of the shower plate 5.

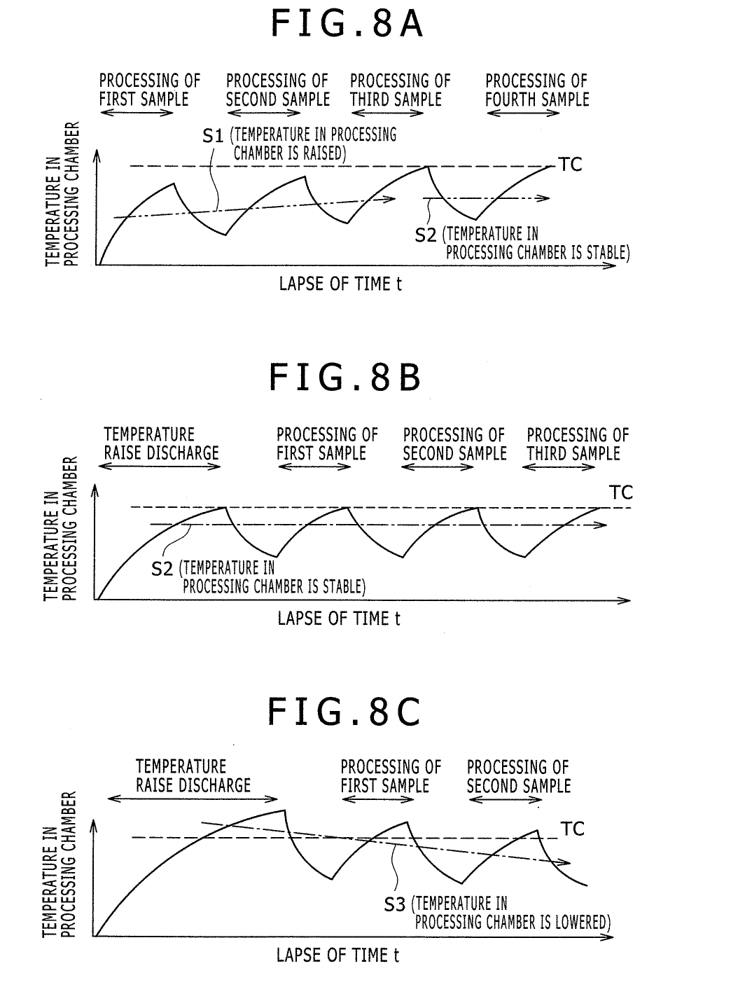

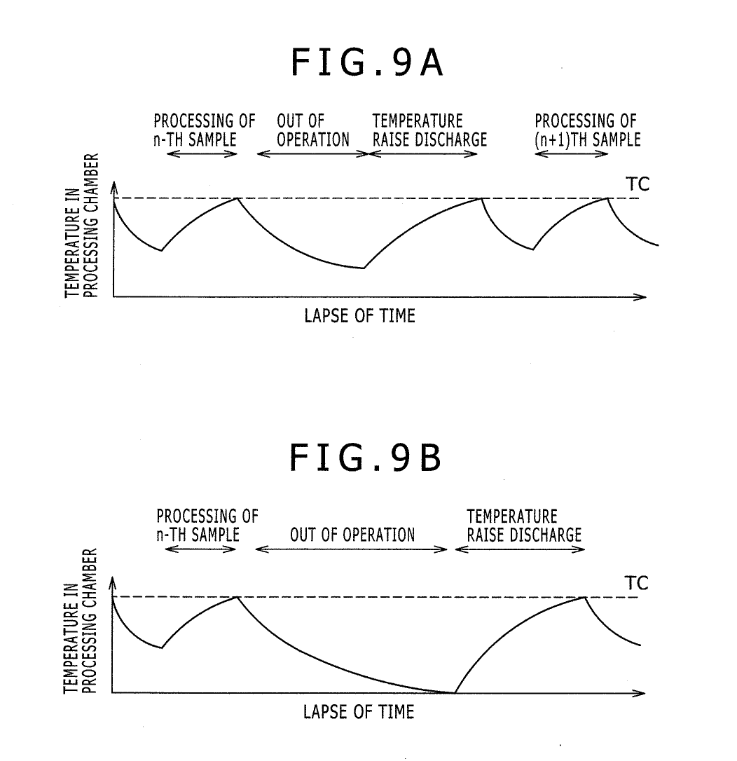

Next, a method of operating the plasma processing apparatus on the basis of the measurement of a rotational temperature will be described with reference to FIGS. 8A to 8C and FIG. 9. FIGS. 8A to 8C show examples of a temperature change in the processing chamber 1 on the basis of the measurement of a rotational temperature when the plasma processing apparatus is again started from a state where the apparatus is not operated. FIG. 8A shows a temperature change when the sample is processed without performing a discharge step for raising temperature. TC designates a target temperature in the processing chamber 1. While the sample to be processed in the processing chamber is processed, the temperature in the processing chamber 1 is raised by heating by plasma and when the processing is finished, the temperature in the processing chamber 1 is lowered. As can be seen from FIG. 8A, in this heat cycle, when comparing, for example, the temperature in the processing chamber 1 at the start of processing the sample or the temperature in the processing chamber 1 immediately before the end of the processing between the samples to be processed, as the processing of the samples advances from the first sample, the second sample, and so on, the temperature in the processing chamber 1 is gradually raised (state S1) and then is brought to a stable state (state S2). This shows the fact that the samples are processed under different temperature conditions, which causes variations in a processed shape between the samples.

For this reason, usually, as shown in FIG. 8B, the processing chamber is warmed by discharge for raising temperature to bring the temperature in the processing chamber into a stable state (state S2) and then the processing of the sample to be processed is performed. When the interior of the processing chamber is heated by the temperature raise discharge, a change in the temperature condition can be prevented between the samples and hence variations in a processed size between the samples to be processed can be reduced.

However, when the temperature raise discharge is excessively performed, as shown in FIG. 8C, the temperature in the processing chamber is excessively raised and is gradually lowered as the processing is repeatedly performed (state S3), which results in having processed the first sample to be processed under a higher processing temperature condition as compared with a case where the sample is processed after several samples are processed. This causes variations in the processed size between the samples. Hence, the time required to perform the temperature raise discharge needs to be suitably determined.

Further, FIGS. 9A and 9B are shown examples in which an idle time (non-operating time) is different from each other. The idle time in FIG. 9A is shorter than in FIG. 9B. In the example in FIG. 9A in which the idle time is shorter, when the temperature raise discharge is performed after the idle time, the discharge time required to raise the temperature in the processing chamber becomes shorter than in FIG. 9B in which the idle time is longer. This is because a decrease in the temperature in the processing chamber is small. In other words, the discharge time required to raise the temperature in the processing chamber needs to be adjusted according to the length of the idle time.

In this embodiment, while the rotational temperature in the processing chamber is measured by a plasma emission monitor for determining an end point of temperature raise discharge, the temperature raise discharge is performed. In other words, as shown in FIG. 5, the gas temperature is measured at the time of the temperature raise discharge; when the gas temperature reaches a specified temperature, for example, the target processing temperature TC shown in FIGS. 8A to 8C, or when it is detected that the quantity of temporal change in the gas temperature reaches a specified value, this is determined as the end point of temperature raise by means for determining an end point of temperature raise discharge and the temperature raise discharge is finished.

For this reason, according to this embodiment, it is possible to determine the state of temperature in the processing chamber on the basis of the measurement of the gas temperature without mounting a thermometer in the processing chamber and hence to find the condition of temperature in the processing chamber even if a thermometer is not mounted in the processing chamber.

### Embodiment 2

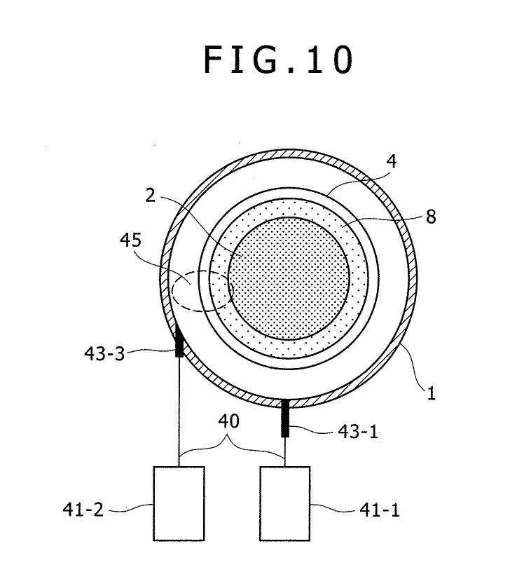

Next, a second embodiment of the present invention will be described with reference to FIG. 10. FIG. 10 is a diagram when the interior of the processing chamber is viewed from the top. The descriptions of the same constituent parts as in FIG. 1 will be omitted. In this apparatus, two light collection heads 43-1 and 43-3 are mounted on the side wall of the processing chamber 1. The light collection head 43-1 is used for measuring the state of plasma directly above the sample and is used for determining an end point of etching, for example. On the other hand, the light collection head 43-3 is used for measuring plasma emission in the area shown as an area 45, that is, near the outer periphery of a wafer 2, or near the wall of the processing chamber 1, or near the outer periphery of the stage 4. This is because the measurement of the gas temperature for raising temperature, as shown in FIG. 7, needs measurement near the outer periphery of the sample to be processed. Of course, even plasma light measured by the use of the light collection head 43-1 without mounting the light collection head 43-3 can include the information of the gas temperature not only near the center of the sample but also near the outer periphery and wall of the sample, so a change in the gas temperature caused by the temperature raise can be measured but the accuracy of measurement will be decreased.

### Embodiment 3

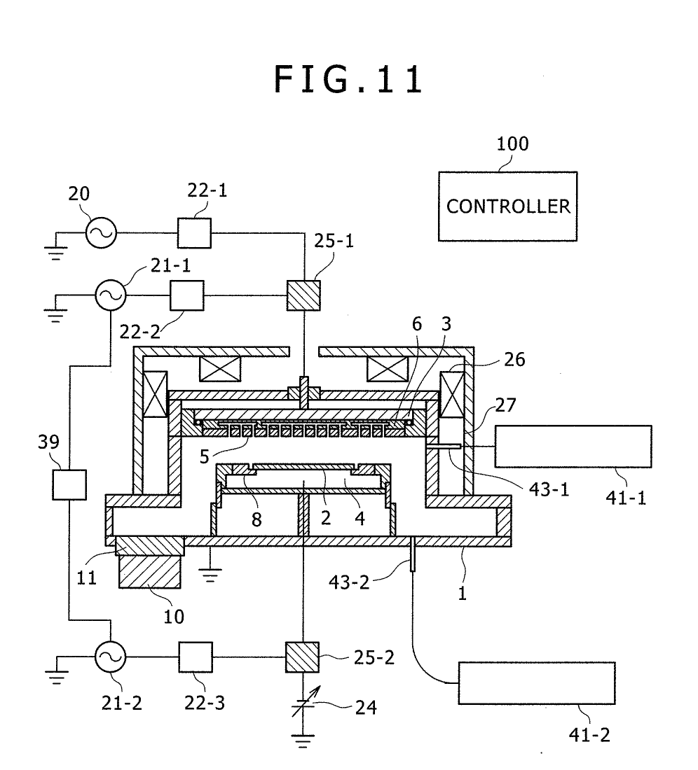

Next, a third embodiment of the present invention will be described by taking FIG. 11 as an example. The descriptions of the same constituent parts as in the embodiment 1 will be omitted. In this apparatus, a light collection heads 43-2 is mounted on the bottom of the processing chamber 1 so as to measure plasma emission near the outer periphery of the sample, near the edge of the stage, or near the wall, and is adapted to measure plasma light developed above from the lower portion of the processing chamber 1. With this, it is possible to measure the gas temperature near the outer periphery in the processing chamber and to determine the state of the temperature rise.

In the respective embodiments described above, the examples have been described in which one or the plurality of light collection heads are mounted so as to measure plasma emission near the outer periphery of the sample. However, in place of this construction, the following construction may be employed: that is, for example, a moving light collection head capable of scanning the sample in a peripheral direction is mounted on the side wall of the processing chamber; the sample is scanned in a plurality of directions by this light collection head; the distribution in the radial direction of an emission spectrum is calculated by Abel conversion; and an emission spectrum near the outside wall and the like of the sample is extracted to calculate the rotational temperature.

What is claimed is:

1. A plasma processing apparatus comprising: a processing chamber for processing a sample to be processed by using a plasma; means for supplying a processing gas to the processing chamber; exhaust means for reducing pressure in the processing chamber; a high-frequency power source for generating the plasma; and a sample holding electrode on which the sample to be processed is placed, the plasma processing apparatus further comprising:
a plasma emission monitor for determining an end point of temperature raise discharge; and a unit for determining an end point of temperature raise discharge, both of which are used for determining an end point of temperature raise discharge performed before the plasma processing.

2. A plasma processing apparatus comprising: a processing chamber for processing a sample to be processed by using a plasma; means for supplying a processing gas to the processing chamber; exhaust means for reducing pressure in the processing chamber; a high-frequency power source for generating the plasma; a sample holding electrode on which the sample to be processed is placed; an upper electrode opposed to the sample holding electrode; and a gas dispersion plate mounted on the upper electrode, the plasma processing apparatus further comprising:
a plasma emission monitor for determining an end point of temperature raise discharge; and a unit for determining an end point of temperature raise discharge, both of which are used for determining an end point of temperature raise discharge performed before the plasma processing,
wherein the gas dispersion plate has a hole through which the plasma emission monitor for determining an end point of temperature raise discharge collects emission from the plasma.

3. A plasma processing apparatus comprising: a processing chamber for processing a sample to be processed by using a plasma; means for supplying a processing gas to the processing chamber; exhaust means for reducing pressure in the processing chamber; a high-frequency power source for generating the plasma; a sample holding electrode on which the sample to be processed is placed; and a plasma processing end point determination plasma emission monitor for determining an end point of the plasma processing, the plasma processing apparatus further comprising:
a plasma emission monitor for determining an end point of temperature raise discharge; and a unit for determining an end point of temperature raise discharge, both of which are used for determining an end point of temperature raise discharge performed before the plasma processing; and
means for calculating a rotational temperature of a gas molecule in the processing chamber from an emission spectrum of plasma collected by the plasma emission monitor for determining an end point of temperature raise discharge.

4. The plasma processing apparatus according to any one of claims 1 to 3,
wherein the plasma emission monitor for determining an end point of temperature raise discharge is disposed at a position where emission from the plasma of an outer peripheral portion of the sample to be processed is collected.

5. The plasma processing apparatus according to claim 1 or claim 2,
wherein the plasma emission monitor for determining an end point of temperature raise discharge collects an emission spectrum of plasma in the processing chamber caused by the temperature raise discharge, and
wherein the unit for determining an end point of temperature raise discharge calculates a rotational temperature of a molecule from the emission spectrum and determines the end point of the temperature raise discharge.

6. The plasma processing apparatus according to claim 4,
wherein the plasma emission monitor for determining an end point of temperature raise discharge is disposed on a side wall of the processing chamber.

7. The plasma processing apparatus according to any one of claims 1 to 3,
wherein the plasma emission monitor for determining an end point of temperature raise discharge has a wavelength resolution of 1 nm or less.

8. The plasma processing apparatus as claimed in claim 3,
wherein the means for calculating a rotational temperature of a gas molecule comprising:
a measured data holding section for holding measured data of a spectrum profile in the processing chamber in a memory, the measured data being measured by the plasma emission monitor for determining an end point of temperature raise discharge;
a spectrum profile data base for holding data of a spectrum profile corresponding to a rotational temperature of a molecule of gas for measuring a rotational temperature, the data being previously found by calculation;
a rotational temperature estimation section for estimating a rotational temperature of the molecule of the gas from a comparison between the measured data of the spectrum profile and the data of the spectrum profile; and
end point determination means for determining an end point of the temperature raise discharge on the basis of the estimated rotational temperature of the molecule of the gas.

9. The plasma processing apparatus according to claim 8,
wherein the spectrum profile data base has spectrum profile data in which the rotational temperature of the gas molecule is previously divided into a plurality of rotational temperatures, and
wherein the rotational temperature estimation section estimates rotational temperature of the gas molecule on the basis of a spectrum profile having a large correlation with any one of the spectrum profiles corresponding to the plurality of rotational temperatures.
